(19) United States
(12) Patent Application Publication
(10) Pub. No.: US 2022/0317147 A1
(43) Pub. Date: Oct. 6, 2022

(54) ELECTRONIC DEVICE

(71) Applicant: DENSO CORPORATION, Kariya-city (JP)

(72) Inventors: KEITARO ITO, Kariya-city (JP); TERUHISA AKASHI, Kariya-city (JP); HIROFUMI FUNABASHI, Kariya-city (JP)

(21) Appl. No.: 17/845,563

(22) Filed: Jun. 21, 2022

Related U.S. Application Data
(63) Continuation of application No. PCT/JP2020/048817, filed on Dec. 25, 2020.

(30) Foreign Application Priority Data
Dec. 25, 2019 (JP) 2019-235222

(51) Int. Cl. G01P 15/08; G01P 15/18; G01P 3/00; G01P 1/00

(52) U.S. Cl. CPC G01P 15/08; G01P 15/18; G01P 3/00; G01P 1/00

(57) ABSTRACT

An electronic device includes: a sensor mounting portion; an inertial force sensor unit detecting an inertial force, the inertial force sensor unit being mounted on the sensor mounting portion; a mounting base substrate arranged in a housing; and a support beam having multiple connection portions connecting with the sensor mounting portion and having multiple connection portions connecting with the mounting base substrate, the support beam includes an angular portion at which an extension direction of the support beam is angled. The mounting base substrate defines a substrate penetration portion that penetrates the mounting base substrate in a thickness direction of the mounting base substrate. The sensor mounting portion is arranged at an inner side of the substrate penetration portion of the mounting base substrate when viewed from the thickness direction of the mounting base substrate.

### CROSS REFERENCE TO RELATED APPLICATIONS

The present application is a continuation application of International Patent Application No. PCT/JP2020/048817 filed on Dec. 25, 2020, which designated the U.S. and claims the benefit of priority from Japanese Patent Application No. 2019-235222 filed on Dec. 25, 2019. The entire disclosures of all of the above applications are incorporated herein by reference.

### TECHNICAL FIELD

The present disclosure relates to an electronic device in which an inertial force sensor unit is arranged on a sensor mounting portion.

### BACKGROUND

There has been known an electronic device in which an inertial force sensor unit is arranged on a sensor mounting portion.

### SUMMARY

The present disclosure provides an electronic device that includes: a sensor mounting portion; an inertial force sensor unit detecting an inertial force, the inertial force sensor unit being mounted on the sensor mounting portion; a mounting base substrate arranged in a housing; and a support beam having multiple connection portions connecting with the sensor mounting portion and having multiple connection portions connecting with the mounting base substrate, the support beam includes an angular portion at which an extension direction of the support beam is angled. The mounting base substrate defines a substrate penetration portion that penetrates the mounting base substrate in a thickness direction of the mounting base substrate. The sensor mounting portion is arranged at an inner side of the substrate penetration portion of the mounting base substrate when viewed from the thickness direction of the mounting base substrate.

### BRIEF DESCRIPTION OF DRAWINGS

Objects, features and advantages of the present disclosure will become apparent from the following detailed description made with reference to the accompanying drawings. In the drawings:

FIG. 1 is a diagram showing a plan view of an electronic device according to a first embodiment of the present disclosure;

FIG. 2 is a diagram showing an enlarged view of a region II shown in FIG. 1;

FIG. 3 is a diagram showing a cross-sectional view taken along a line III-III in FIG. 2;

FIG. 4 is a diagram showing a cross-sectional view taken along a line IV-IV in FIG. 2;

FIG. 5 is a diagram showing a plan view of an electronic device according to a second embodiment of the present disclosure;

FIG. 6 is a diagram showing a plan view of an electronic device according to a third embodiment of the present disclosure;

FIG. 7 is a diagram showing a plan view of an electronic device according to a fourth embodiment of the present disclosure;

FIG. 8 is a diagram showing a plan view of an electronic device according to a fifth embodiment of the present disclosure;

FIG. 9 is a diagram showing a plan view of an electronic device according to a sixth embodiment of the present disclosure;

FIG. 10 is a diagram showing a plan view of an electronic device according to a seventh embodiment of the present disclosure;

FIG. 11 is a diagram showing a cross-sectional view taken along a line XI-XI shown in FIG. 10; and

FIG. 12 is a diagram showing a cross-sectional view taken along a line XII-XII shown in FIG. 10.

### DETAILED DESCRIPTION

Before describing embodiments of the present disclosure, an electronic device which includes an internal force sensor will be described. Conventionally, an electronic device in which an inertial force sensor unit is arranged on a sensor mounting portion is known. For example, in an electronic device, an acceleration sensor used as an inertial force sensor unit is arranged on a printed substrate. In this kind of electronic device, slits are defined in the printed substrate to define a cantilever, and the cantilever is used as the sensor mounting portion. When the cantilever is used as the sensor mounting portion, the acceleration sensor is arranged at a base end of the cantilever.

In a configuration where the sensor mounting portion of the electronic device is provided by the cantilever, the cantilever may be twisted and inclined by application of stress. Thus, the axial direction of acceleration sensor may be changed, and this change may increase an angle detection error thereby decreasing an angle detection accuracy. Further, due to a bending or twist generated when the printed substrate is fixed to a housing or the like, stress may be applied to the acceleration sensor arranged at the base end of the cantilever, and the zero point of acceleration sensor may fluctuate. It should be noted that such difficulty also exists in a case where an angular velocity sensor is used as the inertial force sensor unit.

According to an aspect of the present disclosure, an electronic device includes: a sensor mounting portion; an inertial force sensor unit detecting an inertial force, the inertial force sensor unit being mounted on the sensor mounting portion; a mounting base substrate arranged in a housing; and a support beam having multiple connection portions connecting with the sensor mounting portion and having multiple connection portions connecting with the mounting base substrate, the support beam includes an angular portion at which an extension direction of the support beam is angled. The mounting base substrate defines a substrate penetration portion that penetrates the mounting base substrate in a thickness direction of the mounting base substrate. The sensor mounting portion is arranged at an inner side of the substrate penetration portion of the mounting base substrate when viewed from the thickness direction of the mounting base substrate. The support beam supports the sensor mounting portion that is connected with the mounting base substrate via the support beam.

In the above configuration, the sensor mounting portion is connected with the mounting base substrate via the support beam, that is, supported by the support beam. Thus, when a bending of the mounting base substrate occurs, the bending force caused by the substrate bending is less likely to transfer toward the sensor mounting portion via the support beam. Thus, this configuration can effectively avoid a bending of the sensor mounting portion. As a result, fluctuation of zero point of the inertial force sensor unit, which is caused by the application of the stress, such as the bending force, can be suppressed. The sensor mounting portion is connected to the support beam at multiple connection portions. Thus, this configuration can prevent an inclination of the sensor mounting portion, and it is possible to prevent the inertial force sensor unit from being displaced in the axial direction. As a result, it is possible to prevent a deterioration in detection accuracy of the inertial force sensor unit.

The following describes embodiments of the present disclosure with reference to the drawings. In the following embodiments, the same or equivalent parts are denoted by the same reference symbols.

### First Embodiment

The following will describe an electronic device according to a first embodiment of the present disclosure with reference to the accompanying drawings. The present embodiment will describe about an electronic device constituting a self-position estimation system, which includes a GNSS (abbreviation of global navigation satellite system) and an IMU (abbreviation of inertial measurement unit). For example, the electronic device of the present embodiment may be mounted on a vehicle, which is equipped with a driving support device. The driving support device may supports driving of the vehicle at level three or higher of autonomous driving level defined by the Japanese government or the National Highway Traffic Safety Administration (NHTSA) of United States of America.

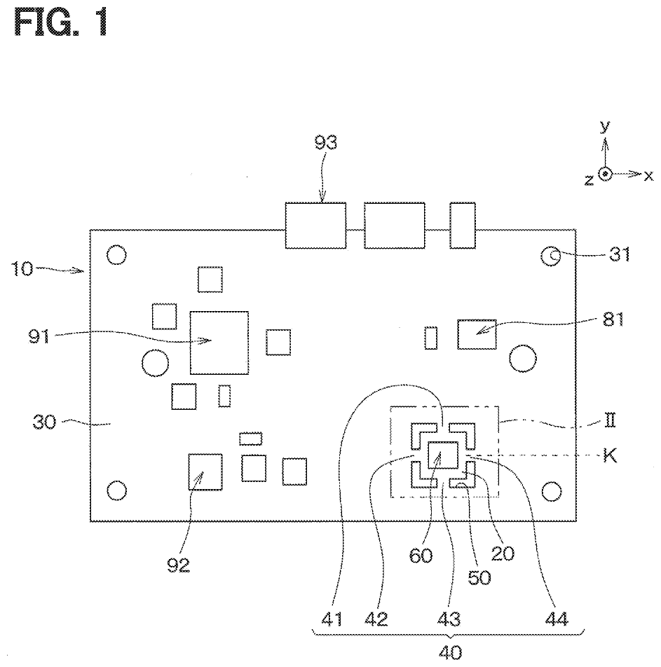

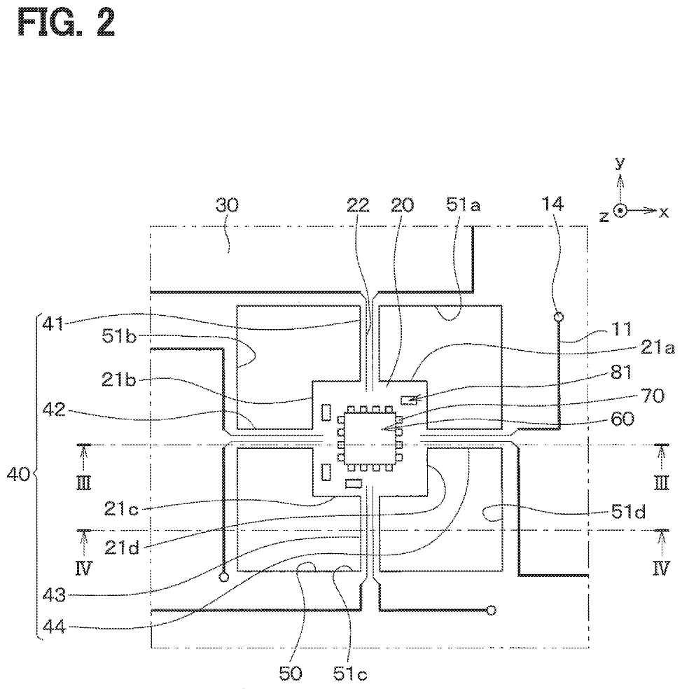

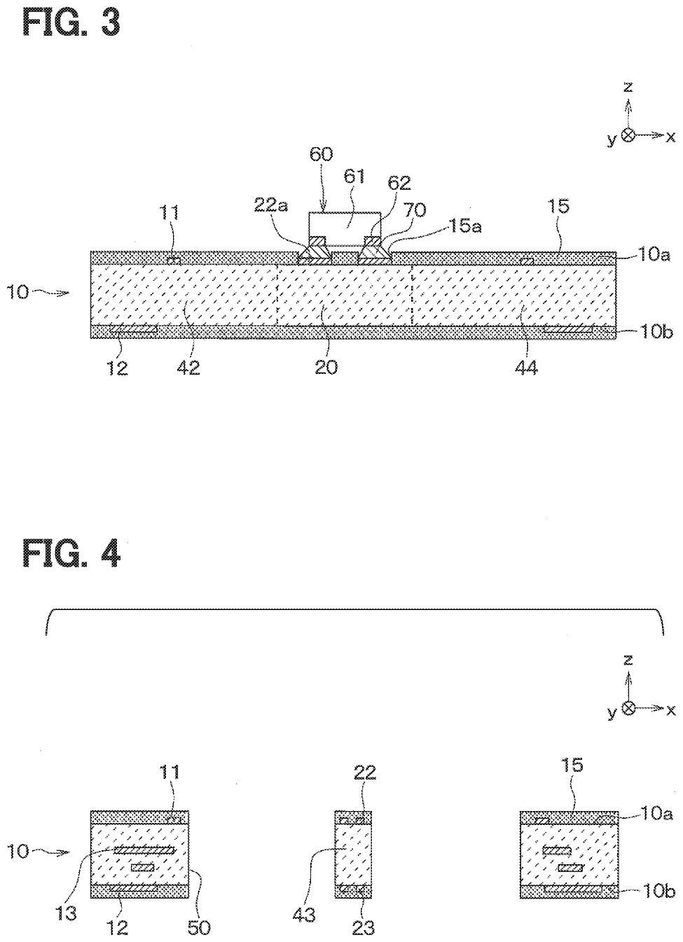

As shown in FIG. 1 to FIG. 4, the electronic device includes a printed substrate 10 and an inertial force sensor unit 60. The printed substrate 10 corresponds to a mounting base. In FIG. 2, for easy understanding, an insulation film 15 that is shown in FIG. 3 is omitted. In FIG. 2, for easy understanding, a wiring pattern 11 or the like, which is covered by the insulation film 15 as shown in FIG. 3, is shown by a solid line. In the following description, a direction along a surface of the printed substrate 10 is defined as an x-axis direction, a direction perpendicular to the x-axis direction along the surface of the printed substrate is defined as a y-axis direction, and a direction perpendicular to both of the x-axis direction and the y-axis direction is defined as a z-axis direction.

The printed substrate 10 of the present embodiment is provided by a glass epoxy substrate or the like. The printed substrate 10 includes wiring patterns 11 and 22 arranged in a first surface portion 10a, wiring patterns 12 and 23 arranged in a second surface portion 10b, and a wiring layer 13 arranged between the one surface portion and the other surface portion. The printed substrate 10 is a multi-layered wiring substrate. The wiring patterns 11 and 22 arranged in the first surface portion 10a, the wiring patterns 12 and 23 arranged in the second surface portion 10b, and the wiring layer 13 arranged inside the printed substrate 10 are electrically connected by one or more vias 14 in appropriate manner.

On the printed substrate 10, an insulation film 15 made of a solder resist or the like is arranged on the first surface portion 10a. Similarly, the insulation film 15 is also arranged on the second surface portion 10b. For example, the insulation film 15 defines contact holes 15a so that lands 22a to be connected with the inertial force sensor unit 60 are exposed from the insulation film within a region corresponding to a sensor mounting portion 20 of the inertial force sensor unit 60.

The printed substrate 10 of the present embodiment includes a sensor mounting portion 20, a peripheral portion 30, and a support beam 40. The sensor mounting portion 20, the peripheral portion 30, and the support beam 40 are partitioned from one another. In the present embodiment, each of the sensor mounting portion 20, the peripheral portion 30, and the support beam 40 is provided by a portion of the printed substrate 10. The sensor mounting portion 20, the peripheral portion 30, and the support beam 40 are arranged on the same surface of the printed substrate.

Specifically, on the printed substrate 10, the sensor mounting portion 20 is arranged at an inner area in a manner that the sensor mounting portion 20 is partitioned from the peripheral portion 30. On the printed substrate 10, the support beam 40 is arranged between the sensor mounting portion 20 and the peripheral portion 30. The printed substrate defines a substrate penetration portion 50, and the support beam 40 is arranged in the substrate penetration portion. The substrate penetration portion 50 may be defined to penetrate the printed substrate 10 in a thickness direction of the printed substrate 10. The substrate penetration portion 50 is configured such that the sensor mounting portion 20 has a square shape or rectangular shape when viewed from a direction perpendicular to the first surface portion 10a of the printed substrate 10. The rectangular sensor mounting portion is defined by four sides including a first mounting portion side 21a to fourth mounting portion side 21d. Hereinafter, the direction perpendicular to the first surface portion 10a of the printed substrate 10 is simply referred to as a normal direction. Further, an arrangement viewed from the direction perpendicular to the first surface portion 10a of the printed substrate 10 may be simply referred to as an arrangement viewed from the normal direction. In the sensor mounting portion 20, the first and the third mounting portion sides 21a and 21c are parallel to the x-axis direction, and the second and the fourth mounting portion sides 21b and 21d are parallel to the y-axis direction.

The substrate penetration portion 50 defines an opening, and a planar shape of the opening viewed from the normal direction is a substantially square shape or a substantially rectangular shape defined by four opening ends. The four opening ends include a first opening end 51a to a fourth opening end 51d. A center of the opening defined by the substrate penetration portion is arranged at a substantially same position as a center of the sensor mounting portion 20. The substrate penetration portion 50 is arranged so that the first opening end 51a faces the first mounting portion side 21a and the second opening end 51b faces the second mounting portion side 21b. The substrate penetration portion 50 is arranged so that the third opening end 51c faces the third mounting portion side 21c and the fourth opening end 51d faces the fourth mounting portion side 21d. In the substrate penetration portion 50, the first and third opening ends 51a and 51c are parallel to the first and third mounting portion sides 21a and 21c, and the second and fourth opening ends 51b and 51d are parallel to the second and fourth mounting portion sides 21b and 21d. In the substrate penetration portion 50, the first and third opening ends 51a and 51c are parallel to the x-axis direction, and the second and fourth opening ends 51b and 51d are parallel to the y-axis direction.

The support beam 40 is connected with both of the sensor mounting portion 20 and the peripheral portion 30. The substrate penetration portion 50 is configured such that the sensor mounting portion 20 is supported by the support beam 40 in a connected manner with the peripheral portion 30. In the present embodiment, the support beam 40 includes four support beam elements, which include a first support beam element 41 to a fourth support beam element 44. Each of the support beam elements has a straight shape extending in a longitudinal direction. The four support beam elements have the same shapes and the same dimensions with one another.

The first support beam element 41 connects the first mounting portion side 21a of the sensor mounting portion 20 with the first opening end 51a of the substrate penetration portion 50. The second support beam element 42 connects the second mounting portion side 21b of the sensor mounting portion 20 with the second opening end 51b of the substrate penetration portion 50. The third support beam element 43 connects the third mounting portion side 21c of the sensor mounting portion 20 with the third opening end 51c of the substrate penetration portion 50. The fourth support beam element 44 connects the fourth mounting portion side 21d of the sensor mounting portion 20 with the fourth opening end 51d of the substrate penetration portion 50. That is, the sensor mounting portion 20 is connected with the peripheral portion 30 in a both-ends support manner by the first to fourth support beam elements 41 to 44.

Specifically, one end of the first support beam element 41 is connected with the first mounting portion side 21a of the sensor mounting portion 20, and the other end of the first support beam element 41 is connected with the first opening end 51a of the substrate penetration portion 50. One end of the second support beam element 42 is connected with the second mounting portion side 21b of the sensor mounting portion 20, and the other end of the second support beam element 42 is connected with the second opening end 51b of the substrate penetration portion 50. One end of the third support beam element 43 is connected with the third mounting portion side 21c of the sensor mounting portion 20, and the other end of the third support beam element 43 is connected with the third opening end 51c of the substrate penetration portion 50. One end of the fourth support beam element 44 is connected with the fourth mounting portion side 21d of the sensor mounting portion 20, and the other end of the fourth support beam element 44 is connected with the fourth opening end 51d of the substrate penetration portion 50.

The first to fourth support beam elements 41 to 44 are arranged in a point-symmetrical manner with respect to the center of the sensor mounting portion 20. The first to fourth support beam elements 41 to 44 pass through the center of the sensor mounting portion 20. The first to fourth support beam elements 41 to 44 are arranged in a line-symmetrical manner with respect to a virtual line extending in the x-axis direction, and are arranged in a line-symmetrical manner with respect to a virtual line extending in the y-axis direction. In the present embodiment, one end of the first support beam element 41 is connected with a center portion of the first mounting portion side 21a of the sensor mounting portion 20, and the other end of the first support beam element 41 is connected with a center portion of the first opening end 51a of the substrate penetration portion 50. The second to fourth support beam elements 42 to 44 have similar arrangements as the first support beam element.

The first to fourth support beam elements 41 to 44 are provided by a part of the printed substrate 10, a thickness of each support beam element is the same as that of the peripheral portion 30 in most part of the support beam element. A part of the support beam element arranged close to the peripheral portion 30, that is, a connection part of the support beam element with the peripheral portion has a cross-sectional area sufficiently smaller than that of the peripheral portion 30. For example, on a cross section along the x-axis direction, the first support beam element 41 has a cross-sectional area that is sufficiently smaller than that of the peripheral portion 30 to which the first support beam element 41 is connected

The first to fourth support beam elements 41 to 44 are provided by a part of the printed substrate 10 as described above. Hereinafter, for convenience of explanation, the wiring patterns arranged in the peripheral portion 30 will be referred to as wiring patterns 11 and 12, and the wiring patterns arranged in the sensor mounting portion 20 and the support beam 40 will be referred to as wiring patterns 22 and 23. In FIG. 2, the wiring pattern 22 arranged around the inertial force sensor unit 60 is omitted for easy understanding. In actual, the wiring pattern 22 is connected to the land 22a to which the inertial force sensor unit 60 is mounted. The wiring pattern 22 is may be arranged around the inertial force sensor unit in an appropriate manner. The first to fourth support beam elements 41 to 44, the wiring patterns 22, 23, and inner side layers of the wirings (not shown) of the present embodiment are arranged so that a configuration of the first surface portion 10a of the printed substrate 10 is symmetrical to a configuration of the second surface portion 10b of the printed substrate 10. For example, in the first surface portion 10a of the printed substrate 10, the wiring pattern 22 arranged in the first to fourth support beam elements 41 to 44 may be a signal wiring for transferring a sensor output signal. In the second surface portion 10b of the printed substrate 10, the wiring pattern 23 arranged in the first to fourth support beam elements 41 to 44 may be a ground wiring.

In the present embodiment, the inertial force sensor unit 60 includes an acceleration sensor that detects an acceleration in the x-axis direction, an acceleration sensor that detects an acceleration in the y-axis direction, and an acceleration sensor that detects an acceleration in the z-axis direction. The inertial force sensor unit 60 includes an angular velocity sensor that detects an angular velocity around the x-axis direction, an angular velocity sensor that detects an angular velocity around the y-axis direction, and an angular velocity sensor that detects an angular velocity around the z-axis direction. That is, the inertial force sensor unit 60 may be a well-known inertial measurement unit (IMU). A specific configuration of the sensors included in the inertial force sensor unit 60 is omitted. The inertial force sensor unit 60 includes a case 61 in which all of the acceleration sensors and the angular velocity sensors are housed and a terminal unit 62 including multiple terminals. The terminal unit 62 is attached to a surface of the case 61. The inertial force sensor unit 60 has a configuration of QFN (abbreviation for Quad Flat No leaded package).

The inertial force sensor unit 60 is electrically connected to the land 22a arranged on the sensor mounting portion 20 via a solder 70. In the present embodiment, the inertial force sensor unit 60 is arranged in a substantially center region of the sensor mounting portion 20. As another example, the inertial force sensor unit 60 may be arranged close to one side of the sensor mounting portion 20. An arrangement position of the inertial force sensor unit 60 is not particularly limited. An external electronic component 81 such as a chip resistor or a chip capacitor may be arranged in the sensor mounting portion 20.

The peripheral portion 30 includes the external electronic component 81, a microcomputer 91, a GNSS component 92, a socket 93 for connecting with another circuit section, or the like. The peripheral portion 30 may define a screw hole 31 through which a screw is inserted for fixing the printed substrate 10 to a housing made of aluminum alloy or the like by screw-fixing. In the present embodiment, the screw hole 31 is defined in a region different from a virtual line K that extends along an extension direction of each of the first to fourth support beam element 41 to 44 at a portion where each support beam element connects with the peripheral portion 30. That is, the screw hole 31 is defined at a position which does not intersect with the virtual line K that extends along the extension direction of each of the first to fourth support beam element 41 to 44 at the portion where each support beam element connects with the peripheral portion 30. FIG. 1 shows only the virtual line K along the extension direction of the fourth support beam element 44. Although it is not shown, the virtual lines K along the extension directions of the first to third support beam elements 41 to 43 are similar to the case of first support beam element.

The above is the configuration of the electronic device according to the present embodiment. For example, the above-described electronic device may be fixed to the housing using the screw, that is, by inserting the screw to the screw hole 31 defined in the peripheral portion 30. Further, a metal lid may be arranged on the housing to accommodate the electronic device inside the housing. The housing together with the lid and components housed inside provides a vehicle mounted component. The vehicle mounted component is mounted on the vehicle by mechanically fixing the housing to the vehicle, and is used to execute various controls of the vehicle.

In the present embodiment, the sensor mounting portion 20 is connected with the peripheral portion 30 by the first to fourth support beam elements 41 to 44. At the connection portions, the cross-sectional areas of the first to fourth support beam elements 41 to 44 are set to be sufficiently smaller than those of the peripheral portion 30. Therefore, even though the peripheral portion 30 of the printed substrate 10 bends around the x-axis direction or in the y-axis direction, a bending force caused by the bending is less likely to transfer toward the sensor mounting portion 20 via the first to fourth support beam elements 41 to 44. Thus, this configuration can avoid a bending of the sensor mounting portion 20. Even though the peripheral portion 30 of the printed substrate 10 is bent, the bending force caused by the bending is absorbed by the first to fourth support beam elements 41 to 44, and a bending of the sensor mounting portion 20 can be avoided. Therefore, it is possible to suppress the axial direction of the inertial force sensor unit 60 from being displaced. Further, it is also possible to suppress fluctuation of zero point of the inertial force sensor unit 60, which is caused by an application of a stress caused by the bending to the inertial force sensor unit 60. Thus, the present embodiment can improve a robustness of the inertial force sensor unit 60 against bending of the substrate. As a result, it is possible to prevent a deterioration in detection accuracy of the inertial force sensor unit 60. Further, since the fluctuation of zero point is less likely to occur in the inertial force sensor unit 60, it is not necessary to perform zero point correction after assembling the electronic device. Thus, it is possible to reduce an adjustment cost and an inspection cost of the component.

The bending of peripheral portion 30 of the printed substrate 10 may be caused by a bending force generated, for example, when the printed substrate 10 is assembled to the housing or the like. The bending force may also be generated in response to a temperature change in a use environment. That is, according to the electronic device of the present embodiment, even though the peripheral portion 30 of the printed substrate 10 is bent by the bending force, it is possible to suppress the deterioration in the detection accuracy of the inertial force sensor unit 60.

The support beam 40 includes the first to fourth support beam elements 41 to 44. The support beam 40 is connected to multiple portions of the sensor mounting portion 20, and is connected to multiple portions of the peripheral portion 30. That is, the sensor mounting portion 20 is supported by the support beam 40 at two or more points. Therefore, it is possible to avoid an inclination of the sensor mounting portion 20, thereby avoiding a decrease in detection accuracy of the sensor unit.

In the present embodiment, the first to fourth support beam elements 41 to 44 are arranged in a point-symmetrical manner with respect to the center of the sensor mounting portion 20. The first to fourth support beam elements 41 to 44 pass through the center of the sensor mounting portion 20. The first to fourth support beam elements 41 to 44 are arranged in a line-symmetrical manner with respect to a virtual line extending in the x-axis direction. The first to fourth support beam elements 41 to 44 are arranged in a line-symmetrical manner with respect to a virtual line extending in the y-axis direction. Therefore, it is possible to further suppress the inclination of the sensor mounting portion 20.

In the electronic device of the present embodiment, as described above, by suppressing the bending of sensor mounting portion 20, degradation in detection accuracy of the inertial force sensor unit 60 can be suppressed. Thus, there is no particular limitation to a configuration of the inertial force sensor unit 60. Therefore, in the inertial force sensor unit 60, each acceleration sensor and each angular velocity sensor can be properly arranged without considering of the bending occurred in the substrate, thereby improving a design convenience of the circuit arrangement. The bending of the sensor mounting portion 20 is suppressed. Thus, it is possible to improve an arrangement design of the inertial force sensor unit 60 in the sensor mounting portion 20.

The sensor mounting portion 20 and the first to fourth support beam elements 41 to 44 are configured by defining the substrate penetration portion 50 on the printed substrate 10. The sensor mounting portion and the support beam elements are provided by a part of the printed substrate 10. Therefore, as compared with a case where the sensor mounting portion 20 and the first to fourth support beam elements 41 to 44 are provided by a different material, it is possible to reduce the number of configuring members and suppress a complexity of the manufacturing process, which in turn leads to a cost reduction.

As described above, a bending of the sensor mounting portion 20 is avoided. Thus, it is possible to suppress an application of stress to the solder 70 arranged between the inertial force sensor unit 60 and the sensor mounting portion 20. Therefore, it is possible to extend the life of solder by preventing the solder 70 from being destroyed, and it is possible to improve a reliability of the electronic device since the life of the solder 70 is extended.

The sensor mounting portion 20 is arranged on inner side of the substrate penetration portion 50. Thus, a compact size can be realized by this arrangement while keeping a partitioned configuration of the sensor mounting portion from the peripheral portion 30. Therefore, an expansion or contraction of the sensor mounting portion 20 caused by the thermal stress can be reduced, and accordingly, a stress applied to the solder 70 can be decreased. Thus, the life of solder 70 can be extended. Herein, the thermal stress may be caused by the temperature change in the usage environment. In addition, fluctuation of the zero point of the sensor unit can be suppressed.

In the peripheral portion 30, the screw hole 31 is defined in a region different from the virtual line K that extends along the extension direction of each of the first to fourth support beam element 41 to 44 at the portion where each support beam element connects with the peripheral portion 30. Compared with a case where the screw hole 31 is defined at a portion intersecting with the virtual line K, the bending force generated in the vicinity of the screw hole 31 due to an assembling of the printed substrate to the housing or the like is less likely to transfer toward the support beam elements 41 to 44, thereby suppressing a bending of the sensor mounting portion 20.

In the electronic device of the present embodiment, as described above, the inertial force sensor unit 60 is provided by an IMU, and is used to configure a self-position estimation system. As described above, in the inertial force sensor unit 60, a displacement of the axial direction and fluctuation of the zero point can be suppressed. Thus, the inertial forces along six axes can be detected with high accuracy. Therefore, the electronic device of the present embodiment can provide dead reckoning (that is, inertial navigation) of the vehicle for a long period.

### Second Embodiment

The following describes a second embodiment of the present disclosure. The present embodiment is a modification of the configuration of the support beam 40 of the first embodiment. The remaining configuration is similar to that of the first embodiment, and will thus not be described repeatedly.

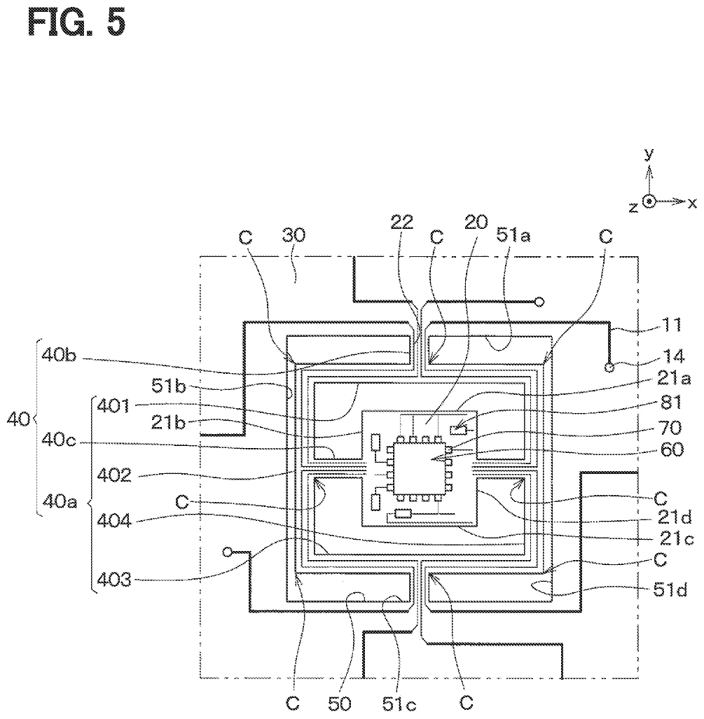

In the present embodiment, as shown in FIG. 5, the support beam 40 includes a frame portion 40a having a frame shape, an outer support portion 40b, and an inner support portion 40c. FIG. 5 is an enlarged view of a region II shown in FIG. 1.

The frame portion 40a includes first to fourth elements 401 to 404, each of which has a straight shape. The first element 401 is arranged between the first mounting portion side 21a and the first opening end 51a, and is parallel to the x-axis direction. The second element 402 is arranged between the second mounting portion side 21b and the second opening end 51b, and is parallel to the y-axis direction. The third element 403 is arranged between the third mounting portion side 21c and the third opening end 51c, and is parallel to the x-axis direction. The fourth element 404 is arranged between the fourth mounting portion side 21d and the fourth opening end 51d, and is parallel to the y-axis direction.

The frame portion 40a is configured such that the first to fourth elements 401 to 404 are integrated as one body. The frame portion 40a has a rectangular frame shape, which has angular portions C. The frame portion 40a curves at each angular portion C in a direction perpendicular to the extending direction of each element 401, 402, 403, 404.

The outer support portion 40b includes two elements each of which has a straight shape. One element of the outer support portions 40b is arranged along the y-axis direction, and is connected with a center portion of the first opening end 51a and a center portion of the first element 401 of the frame portion 40a. The other element of the outer support portions 40b is arranged along the y-axis direction, and is connected with a center portion of the third opening end 51c and a center portion of the third element 403 of the frame portion 40a.

The inner support portion 40c includes two elements each of which has a straight shape. One element of the inner support portions 40c is arranged along the x-axis direction, and is connected with a center portion of the second mounting portion side 21b and a center portion of the second element 402 of the frame portion 40a. The other element of the inner support portions 40c is arranged along the x-axis direction, and is connected with a center portion of the fourth mounting portion side 21d and a center portion of the fourth element 404 of the frame portion 40a.

The support beam 40 of the present embodiment has a gimbal-like structure. The support beam 40 of the present embodiment is arranged in a point-symmetrical manner with respect to the center of the sensor mounting portion 20. The support beam 40 of the present embodiment passes through the center of the sensor mounting portion 20. The support beam 40 is arranged in a line-symmetrical manner with respect to a virtual line extending in the x-axis direction. The support beam 40 is arranged in a line-symmetrical manner with respect to a virtual line extending in the y-axis direction.

In the present embodiment, the sensor mounting portion 20 is supported within the peripheral portion 30 by the two elements of outer support portion 40b, which are connected to the peripheral portion 30 and the two elements of inner support portion 40c, which are connected to the sensor mounting portion 20. That is, the sensor mounting portion 20 is supported at two points by the support beam 40 within the peripheral portion 30.

In the present embodiment, by connecting the frame portion 40a and the outer support portion 40b as described above, the angular portions C are configured such that an extension direction of one connection part is perpendicular to an extension direction of the other connection part at each angular portion C. By connecting the frame portion 40a and the inner support portion 40c as described above, the angular portions C are configured such that an extension direction of one connection part is perpendicular to an extension direction of the other connection part at each angular portion C.

In the present embodiment, the support beam 40 includes the angular portions C. Therefore, when the printed substrate 10 is bent by a stress, the bending force propagated from the printed substrate 10 through the support beam 40 is likely to be concentrated on the angular portions C of the support beam 40, and is less likely to transfer toward the sensor mounting portion 20. Therefore, it is possible to further suppress the bending of the sensor mounting portion 20 and further suppress the deterioration in detection accuracy of the inertial force sensor unit 60.

The support beam 40 includes the angular portions C. Thus, it is easy to increase a length of the support beam 40 compared with a case where the sensor mounting portion 20 and the peripheral portion 30 are connected with one another by the support beam 40 having the straight structure. Therefore, the bending force propagated from the printed substrate 10 through the support beam 40 is likely to be absorbed by the support beam 40 in more efficient manner. Therefore, bending of the sensor mounting portion 20 can be further suppressed.

### Third Embodiment

The following describes a third embodiment of the present disclosure. The present embodiment is a modification of the configuration of the support beam 40 of the first embodiment. The remaining configuration is similar to that of the first embodiment, and will thus not be described repeatedly.

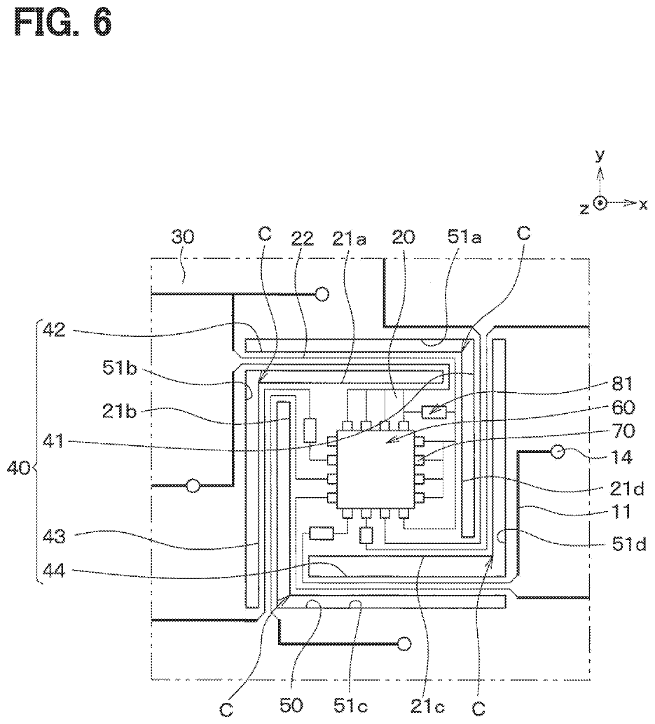

In the present embodiment, as shown in FIG. 6, the support beam 40 has first to fourth support beam elements 41 to 44 each of which is angled at an angular portion C. Specifically, each of the first to fourth support beam elements 41 to 44 has one angular portion C, and an extension direction of the support beam element is changed in perpendicular manner at the angular portion C. FIG. 6 is an enlarged view of a region II shown in FIG. 1.

In the first support beam element 41, one end is connected to an end of the fourth mounting portion side 21d, which is close to the third opening end 51c, and the other end is connected with a part of the first opening end 51a, which does not face the first mounting portion side 21a. In the second support beam element 42, one end is connected to an end of the first mounting portion side 21a, which is close to the fourth opening end 51d, and the other end is connected with a part of the second opening end 51b, which does not face the second mounting portion side 21b.

In the third support beam element 43, one end is connected to an end of the second mounting portion side 21b, which is close to the first opening end 51a, and the other end is connected with a part of the third opening end 51c, which does not face the third mounting portion side 21c. In the fourth support beam element 44, one end is connected to an end of the third mounting portion side 21c, which is close to the second opening end 51b, and the other end is connected with a part of the fourth opening end 51d, which does not face the fourth mounting portion side 21d.

The support beam 40 of the present embodiment has a fylfot shape, which is a cross with perpendicular extensions. The support beam 40 of the present embodiment is arranged in a point-symmetrical manner with respect to the center of the sensor mounting portion 20.

In the present embodiment, since the first to fourth support beam elements 41 to 44 have the respective angular portions C, the same effect as that of the second embodiment can be provided.

### Fourth Embodiment

The following describes a fourth embodiment of the present disclosure. The present embodiment is a modification of the configuration of the support beam 40 of the third embodiment. The remaining configuration is similar to that of the third embodiment, and will thus not be described repeatedly.

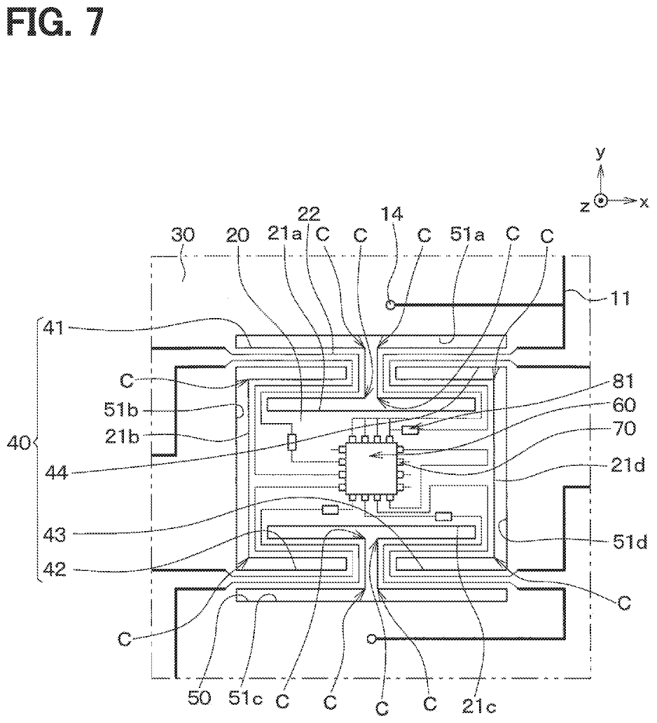

In the present embodiment, as shown in FIG. 7, each of first to fourth support beam elements 41 to 44 has three angular portions C, and an extension direction of each support beam element is changed in perpendicular manner at each of three angular portions C. FIG. 7 is an enlarged view of a region II shown in FIG. 1.

In the first support beam element 41, one end is connected to an end of the first mounting portion side 21a, which is close to the second opening end 51b, and the other end is connected with a part of the second opening end 51b, which does not face the second mounting portion side 21b. In the second support beam element 42, one end is connected to an end of the third mounting portion side 21c, which is close to the second opening end 51b, and the other end is connected with a part of the second opening end 51b, which does not face the second mounting portion side 21b.

In the third support beam element 43, one end is connected to an end of the third mounting portion side 21c, which is close to the fourth opening end 51d, and the other end is connected with a part of the fourth opening end 51d, which does not face the fourth mounting portion side 21d. In the fourth support beam element 44, one end is connected to an end of the first mounting portion side 21a, which is close to the fourth opening end 51d, and the other end is connected with a part of the fourth opening end 51d, which does not face the fourth mounting portion side 21d.

Each of the first to fourth support beam elements 41 to 44 is curved so that a length in the x-axis direction is longer than a length in the y-axis direction. The support beam 40 of the present embodiment is arranged in a point-symmetrical manner with respect to the center of the sensor mounting portion 20. The support beam 40 of the present embodiment passes through the center of the sensor mounting portion 20, and is arranged in a line-symmetrical manner with respect to a virtual line extending in the x-axis direction, and is arranged in a line-symmetrical manner with respect to a virtual line extending in the y-axis direction.

In the present embodiment, the sensor mounting portion 20 has a planar rectangular shape defined by the first and third mounting portion sides 21a and 21c as long sides and the second and fourth mounting portion sides 21b and 21d as short sides. That is, the sensor mounting portion 20 has the first mounting portion side 21a to which the first and fourth support beam elements 41 and 44 are connected, and the third mounting portion side to which the second and third support beam elements 42 and 43 are connected. The first and third mounting portion sides 21a and 21c correspond to the long sides of the planar rectangular shape of the sensor mounting portion 20.

In the present embodiment, each support beam element 41, 42, 43, 44 includes three angular portions C. Therefore, when the printed substrate 10 is bent by a stress, the bending force propagated from the printed substrate 10 through the support beam elements 41 to 44 is likely to be concentrated on the angular portions C of each support beam element of the support beam 40, and is less likely to transfer toward the sensor mounting portion 20. Therefore, bending of the sensor mounting portion 20 can be further suppressed.

In the present embodiment, the sensor mounting portion 20 has the first mounting portion side 21a to which the first and fourth support beam elements 41 and 44 are connected, and the third mounting portion side to which the second and third support beam elements 42 and 43 are connected. The first and third mounting portion sides 21a and 21c correspond to the long sides of the planar rectangular shape of the sensor mounting portion 20. Therefore, the lengths of the first to fourth support beam elements 41 to 44 in the x-axis direction can be easily increased, and bending force can be easily absorbed by the first to fourth support beam elements 41 to 44. Therefore, bending of the sensor mounting portion 20 can be further suppressed.

### Fifth Embodiment

The following describes a fifth embodiment of the present disclosure. The present embodiment is a modification of the configuration of the support beam 40 of the first embodiment. The remaining configuration is similar to that of the first embodiment, and will thus not be described repeatedly.

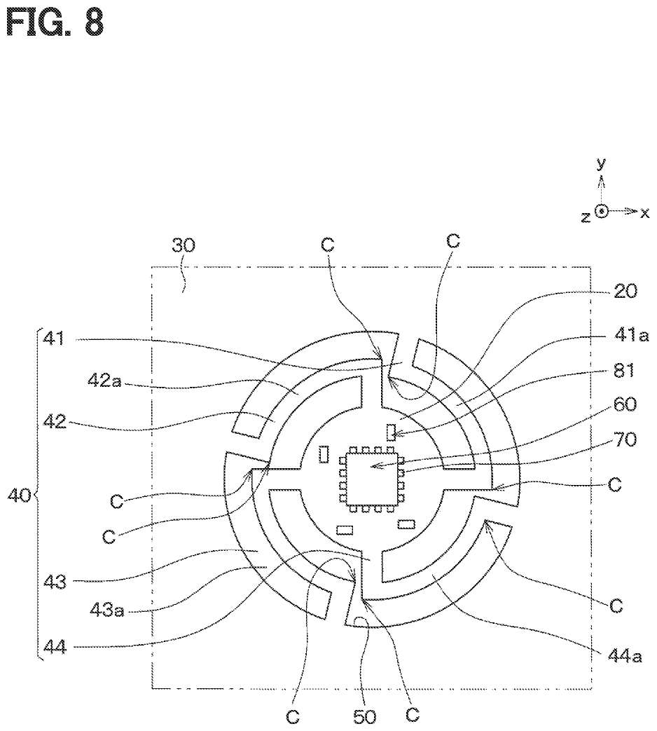

In the present embodiment, as shown in FIG. 8, the sensor mounting portion 20 has a circular shape viewed from the normal direction. The substrate penetration portion 50 also has a circular shape and is concentric with an outer periphery of the sensor mounting portion 20. FIG. 8 is an enlarged view of a region II shown in FIG. 1. In FIG. 8, the wiring patterns 11, 22 and the like arranged on the sensor mounting portion 20 and the like are omitted for simplification purpose.

In the present embodiment, the sensor mounting portion 20 is connected with the peripheral portion 30 by the first to fourth support beam elements 41 to 44. In the present embodiment, each of the first to fourth support beam elements 41 to 44 has two angular portions. In each support beam element 41, 42, 43, 44, a first angular portion 41a, 42a, 43a, 44a is curved along the outer periphery of the sensor mounting portion 20, and a second angular portion 41b, 42b, 43b, 44b curves at a different direction from the curve direction of the first angular portion. The first to fourth support beam elements 41 to 44 are arranged in a point-symmetrical manner with respect to the center of the sensor mounting portion 20.

In the present embodiment, although the sensor mounting portion 20 has the circular shape, the same effect as that of the first embodiment can be provided. In the present embodiment, since each of the first to fourth support beam elements 41 to 44 has two angular portions C, the same effect as that of the second embodiment can be provided. That is, the bending of the sensor mounting portion 20 can be suppressed.

### Sixth Embodiment

The following describes a sixth embodiment of the present disclosure. The present embodiment is a modification of the configuration of the support beam 40 of the first embodiment. The remaining configuration is similar to that of the first embodiment, and will thus not be described repeatedly.

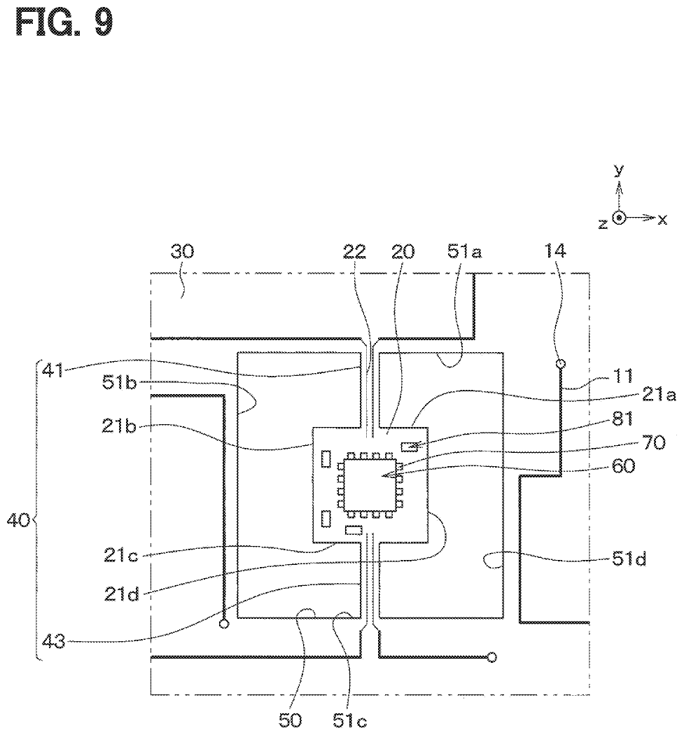

In the present embodiment, as shown in FIG. 9, the support beam 40 includes two support beam elements. The two support beam elements may be the first support beam element 41 and the third support beam element 43 described in the first embodiment. Alternatively, the two support beam elements may be the second support beam element 42 and the fourth support beam element 44 described in the first embodiment.

In the present embodiment, although the support beam 40 includes two support beam elements, such as the first and third support beam elements 41 and 43 or the second or fourth support beam elements 42 and 44, the sensor mounting portion 20 is supported at two points by the support beam 40. Thus, the same effect as that of the first embodiment can be provided.

### Seventh Embodiment

The following describes a seventh embodiment of the present disclosure. The present embodiment is a modification of the configurations of the support beam 40 and the sensor mounting portion 20 of the third embodiment. The remaining configuration is similar to that of the first embodiment, and will thus not be described repeatedly.

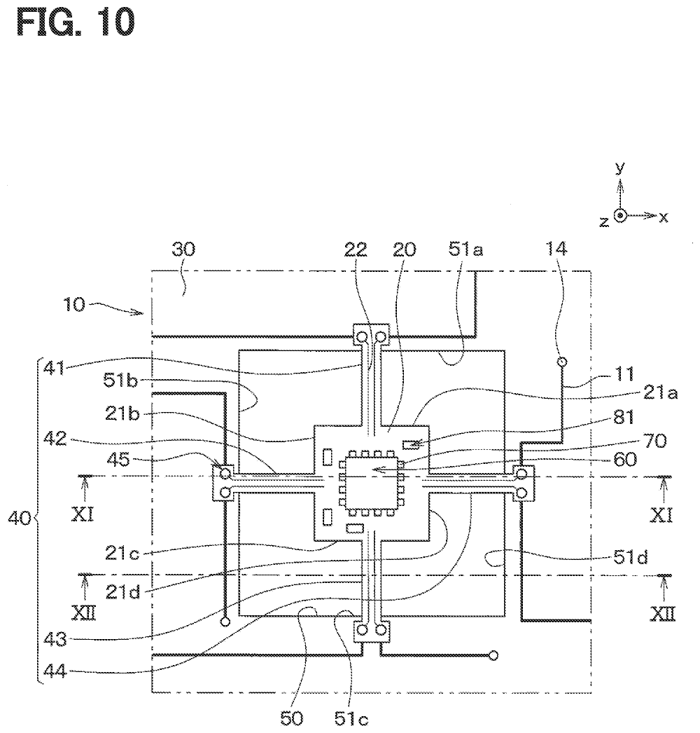

In the present embodiment, as shown in FIG. 10 to FIG. 12, the sensor mounting portion 20 is made of different material from that of the printed substrate 10. In the present embodiment, the sensor mounting portion 20 is made of a ceramic substrate having a higher rigidity than that of the glass epoxy substrate constituting the printed substrate 10. The sensor mounting portion 20 includes a wiring pattern 22 arranged on one surface 20a of the sensor mounting portion 20, and an insulation film 24 is arranged on the wiring pattern 22 to cover the wiring pattern. For example, the insulation film 24 defines contact holes 24a so that lands 22a to be connected with the inertial force sensor unit 60 are exposed from the insulation film 24. The lands 22a may be provided by a part of the wiring pattern 22.

The inertial force sensor unit 60 is electrically connected to the land 22a arranged on the sensor mounting portion 20 via a solder 70.

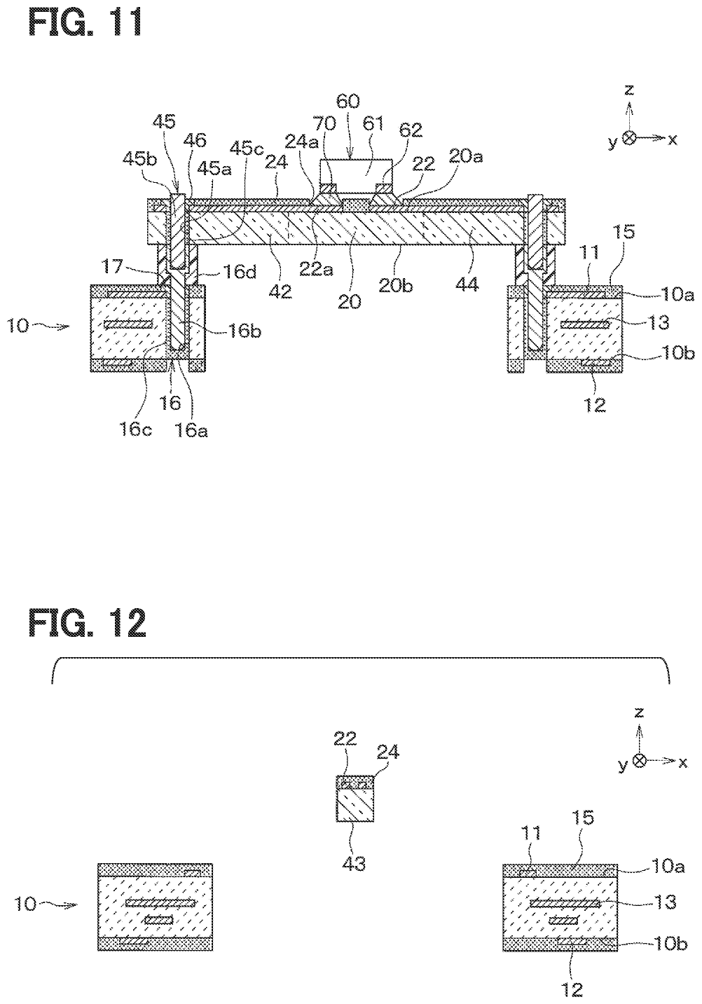

In the present embodiment, first to fourth support beam elements 41 to 44 are integrated with the sensor mounting portion 20 as one body. In the present embodiment, the first to fourth support beam elements 41 to 44 are provided by a part of the ceramic substrate. The wiring patterns 22 arranged in the sensor mounting portion 20 may be appropriately extended along the first to fourth support beam elements 41 to 44. FIG. 11 is a cross-sectional view taken along a line XI-XI in FIG. 10. Although the line XI-XI does not pass through the wiring pattern 22 arranged on the second and fourth support beam element 42 and 44, the wiring pattern 22 is also shown in the cross-sectional view for easy understanding.

The first support beam element 41 extends in the y-axis direction from a center portion of the first mounting portion side 21a. The second support beam element 42 extends in the x-axis direction from a center portion of the second mounting portion side 21b. The third support beam element 43 extends in the y-axis direction from a center portion of the third mounting portion side 21c. The fourth support beam element 44 extends in the x-axis direction from a center portion of the fourth mounting portion side 21d. When viewed from the normal direction, a center of the sensor mounting portion 20 is positioned at the same position as a center of the substrate penetration portion 50. Under this configuration, the sensor mounting portion 20 has dimensions such that an end portion of the sensor mounting portion 20 and an opposite end portion of the sensor mounting portion 20 overlap with the printed substrate 10.

Each of the first to fourth support beam elements 41 to 44 includes a beam connection portion 45 arranged at an end of the support beam element, which is opposite to the sensor mounting portion 20. Each beam connection portion 45 has a male type connection pin 45b arranged in a hole 45a, which is defined to penetrate the corresponding support beam element 41, 42, 43, 44. The connection pin 45b projects from the openings on both ends of the hole 45a. The connection pin 45b is fixed by a fixing member 45c, such as an adhesive arranged in the hole 45a.

The wiring pattern 22 arranged on the first to fourth support beam elements 41 to 44 are appropriately extended to the vicinity of the holes 45a. On one opening of the hole 45a on a first surface portion 20a of the sensor mounting portion 20, a solder 46 is arranged to electrically connect the connection pin 45b and the wiring pattern 22. As a result, the inertial force sensor unit 60 is electrically connected to the connection pin 45b via the wiring pattern 22.

The printed substrate 10 defines a substrate penetration portion 50 similar to the above-described substrate penetration portion 50. A substrate connection portion 16 is arranged around the substrate penetration portion 50. The printed substrate 10 of the present embodiment only has the peripheral portion 30 as compared with printed substrate 10 of the first embodiment.

In the present embodiment, the center of the sensor mounting portion 20 and the center of the substrate penetration portion 50 coincide with each other in the normal direction, and each of the beam connection portion 45 arranged in each support beam element 41, 42, 43, 44 overlaps with the printed substrate 10 in the normal direction. The printed substrate 10 has the substrate connection portions 16 at positions, respectively, corresponding to the beam connection portions 45 of the first to fourth support beam elements 41 to 44. Each substrate connection portion 16 has a female type connection pin 16b arranged in a hole 16a defined to penetrate the printed substrate 10.

Each substrate connection pin 16b projects from one surface portion 10a of the printed substrate 10 through the hole 16a. The connection pin 16b is fixed by a fixing member 16c, such as an adhesive arranged in the hole 16a. Further, a resin member 16d for insulation purpose may be arranged around a portion of the connection pin 16b which protrudes from the printed substrate 10.

Further, the wiring pattern 11 arranged on the one surface portion 10a of the printed substrate 10 is appropriately extended to the vicinity of the hole 16a. On one opening of the hole 16a on the first surface portion 10a of the printed substrate 10, a solder 17 is arranged to electrically connect the connection pin 16b and the wiring pattern 11.

The sensor mounting portion 20 is arranged on the printed substrate 10, thereby the connection pin 45b of the beam connection portion 45 fitting with the connection pin 16b of the substrate connection portion 16. Thus, the sensor mounting portion 20 and the printed substrate 10 are mechanically and electrically connected with one another. In the electronic device of the present embodiment, the printed substrate 10, the sensor mounting portions 20, and the first to fourth support beam elements 41 to 44 are not arranged on the same surface.

In the present embodiment, when viewed from the normal direction, the screw hole 31 is arranged at a position which does not intersect with the virtual line K that extends along the extension direction of each of the first to fourth support beam element 41 to 44 at the portion where each support beam element connects with the peripheral portion 30.

In the present embodiment described above, the printed substrate 10 includes the substrate penetration portion 50. When the printed substrate 10 is bent around the x-axis direction or the y-axis direction, the bending force can be divided by the substrate penetration portion 50. Therefore, in the electronic device of the present embodiment, the bending force around the substrate penetration portion 50 (that is, a position where the substrate connection portion 16 is arranged) can be reduced as compared with the case where the substrate penetration portion 50 is not defined. That is, when the printed substrate 10 is bent, the bending force that is propagated toward the sensor mounting portion 20 via the substrate connection portion 16 can be reduced in proper manner.

The sensor mounting portion 20 is supported, by the first to fourth support beam elements 41 to 44, the beam connection portion 45, and the substrate connection portion 16, on the printed substrate 10. Therefore, when the printed substrate 10 is bent, the bending force due to the bending is less likely to propagate through the substrate connection portion 16, the first to fourth support beam elements 41 to 44, and the beam connection portion 45. Therefore, it is possible to suppress the bending of the sensor mounting portion 20, and it is possible to obtain the same effect as that of the first embodiment.

The sensor mounting portion 20 and the support beam 40 are configured by using a material different from that of the printed substrate 10. Therefore, the sensor mounting portion 20 can be made of a material suitable for the intended use, and the circuit design can be carried out in more flexible manner.

In the present embodiment, the sensor mounting portion 20 and the support beam 40 are provided by a part of the ceramic substrate having a higher rigidity than that of the printed substrate 10. Therefore, even though the printed substrate 10 is bent, the support beam 40 and the sensor mounting portion 20 are less likely to bend compared with the printed substrate 10.

### Other Embodiments

Although the present disclosure has been described in accordance with the foregoing embodiments, it is understood that the present disclosure is not limited to the above embodiments or structures. The present disclosure also includes various modification examples or variations within the scope of equivalents. In addition, the present disclosure also includes various combinations and configurations, as well as other combinations and configurations that include only one element, more, or less within the scope and spirit of the present disclosure.

For example, in each of the above embodiments, the printed substrate 10 corresponding to the mounting base may be made of ceramic substrate or the like, instead of the glass epoxy substrate. In each of the above embodiments, the inertial force sensor unit 60 does not have to include all of the three acceleration sensors and three angular velocity sensors. For example, the inertial force sensor unit 60 may include two or less acceleration sensors, or may include two or less angular velocity sensors. The inertial force sensor unit 60 may include only one or more acceleration sensors. Alternatively, the inertial force sensor unit 60 may include only one or more angular velocity sensor.

In each of the above embodiments, the inertial force sensor unit 60 may have another structure different from QFN, for example, QFP (abbreviation of Quad Flat Package) structure that has a terminal portion protruding from the case 61. Further, the inertial force sensor unit 60 may be mechanically attached to the sensor mounting portion 20 via an adhesive or the like, and is electrically connected to the land 22a or the like arranged on the sensor mounting portion 20 by a bonding wire or the like.

In each of the above embodiments, the shape of the sensor mounting portion 20 can be appropriately changed. For example, the sensor mounting portion 20 may have a circular shape as in the fifth embodiment, a triangular shape, or a polygonal shape, such as a pentagon. Similarly, the shape of the opening of the substrate penetrating portion 50 can be appropriately changed. For example, the opening of the substrate penetrating portion 50 may have a circular shape as in the fifth embodiment, or may have a triangular shape or a polygonal shape, such as pentagon.

In each of the above embodiments, the support beam 40 do not have to be arranged point-symmetrically with respect to the center of the sensor mounting portion 20. The support beam 40 does not have to be arranged symmetrically with respect to the virtual line that passes through the center of the sensor mounting portion 20 parallel to the x-axis direction. The support beam 40 does not have to be arranged symmetrically with respect to the virtual line that passes through the center of the sensor mounting portion 20 parallel to the y-axis direction. For example, in the first embodiment, the first to fourth support beam elements 41 to 44 are connected to the first to fourth mounting portion sides 21a to 21d, respectively. The first to fourth support beam elements 41 to 44 are connected to the first to fourth opening ends 51a to 51d, respectively. By changing the connection portions of the first to fourth support beam elements 41 to 44 with the first to fourth mounting portion sides 21a to 21d and the first to fourth opening ends 51a to 51d, the first to fourth support beam elements may be arranged in different manner other than the point-symmetrical manner or the line-symmetrical manner. For example, as in the sixth embodiment, the support beam 40 may include two support beam elements, such as the first support beam element 41 and the second support beam element 42.

In the first, third to seventh embodiments, the first to fourth support beam elements 41 to 44 do not have to be in the same shape and the same dimension with one another. In the first to sixth embodiments, the sensor mounting portion 20 may have one or more vias 14, or may have a wiring layer, which corresponds to the wiring layer 13 of the peripheral portion 30, in the sensor mounting portion 20 or in the first to fourth support beam elements 41 to 44.

In the seventh embodiment, the attachment of the sensor mounting portion 20 to the printed substrate 10 may be configured as follows. For example, the connection pin 45b on the sensor mounting portion side may be provided by a female type pin, and the connection pin 16b on the substrate side may be provided by a male type pin. For another example, a common pin may be inserted in both of the hole 45a defined in the first to fourth support beam elements 41 to 44 and the hole 16a defined in the printed substrate 10.

The above-described embodiments may be combined with one another as appropriate. For example, the second to sixth embodiments may be appropriately combined with the seventh embodiment so that the configuration of the support beam 40 in the seventh embodiment is changed in proper manner. The combination of two or more above-described embodiments may be further combined with another embodiment.

What is claimed is:

1. An electronic device comprising:
a sensor mounting portion;
an inertial force sensor unit detecting an inertial force, the inertial force sensor unit being mounted on the sensor mounting portion;
a mounting base substrate arranged in a housing; and
a support beam having multiple connection portions connecting with the sensor mounting portion and having multiple connection portions connecting with the mounting base substrate, the support beam includes an angular portion at which an extension direction of the support beam is angled,
wherein
the mounting base substrate defines a substrate penetration portion that penetrates the mounting base substrate in a thickness direction of the mounting base substrate,
the sensor mounting portion is arranged at an inner side of the substrate penetration portion of the mounting base substrate when viewed from the thickness direction of the mounting base substrate, and
the support beam supports the sensor mounting portion that is connected with the mounting base substrate via the support beam.

2. The electronic device according to claim 1, wherein
the multiple connection portions of the support beam, which connect with the sensor mounting portion, include at least two connection portions, and
the sensor mounting portion is supported by the support beam via the at least two connection portions.

3. The electronic device according to claim 2, wherein
the support beam is arranged in a point symmetrical manner with respect to a center of the sensor mounting portion, and
the support beam is arranged in a line symmetry manner with respect to a virtual line passing through the center of the sensor mounting portion.

4. The electronic device according to claim 1, wherein
the support beam includes multiple support beam elements, which have an identical shape and an identical dimension.

5. The electronic device according to claim 1, wherein
the sensor mounting portion and the support beam are provided by a part of the mounting base substrate, and
the sensor mounting portion and the support beam are integrated with the mounting base substrate as one body.

6. The electronic device according to claim 1, wherein
the sensor mounting portion is provided by a material different from a material of the mounting base substrate.

7. The electronic device according to claim 6, wherein
the material of the sensor mounting portion has a higher rigidity than a rigidity of the material of the mounting base substrate.

8. The electronic device according to claim 1, wherein
the inertial force sensor unit is electrically connected to the sensor mounting portion via a solder.

9. The electronic device according to claim 1, wherein
the mounting base substrate includes a peripheral portion arranged at an outer side of the substrate penetration portion,
the support beam is connected to the peripheral portion of the mounting base substrate,
the mounting base substrate defines a screw hole in the thickness direction of the mounting base substrate,
the screw hole receives a fixing member by which the mounting base substrate is fixed to the housing, and
when viewed from the thickness direction of the mounting base substrate, the screw hole is arranged in the peripheral portion at a position different from a position of a virtual line that passes through a longitudinal direction of each of the multiple connection portions of the support beam.
